(19) United States
(12) Patent Application Publication
(10) Pub. No.: US 2024/0371705 A1
(43) Pub. Date: Nov. 7, 2024

(54) WAFER BONDING APPARATUS AND METHOD

(71) Applicant: Taiwan Semiconductor Manufacturing Company, Ltd., Hsinchu (TW)

(72) Inventors: Jeng-Nan HUNG, Taichung City (TW); Chen-Hua YU, Hsinchu City (TW); Tung-Li WU, Hsinchu City (TW); Chung-Jung WU, Hsinchu City (TW)

(21) Appl. No.: 18/312,012

(22) Filed: May 4, 2023

(51) Int. Cl. H01L 21/66; H01L 21/67; H01L 21/683; H01L 23/00

(52) U.S. Cl. CPC H01L 22/12; H01L 21/67121; H01L 21/6838; H01L 24/80; H01L 2224/80201

(57) ABSTRACT

A wafer bonding apparatus is provided. The wafer bonding apparatus includes a first wafer chuck, a second wafer chuck, and a plurality of bonding pins. The first wafer chuck is configured to hold a first wafer. The second wafer chuck is configured to hold a second wafer. The bonding pins are accommodated in the first wafer chuck and configured to be movable through the first wafer chuck to apply pressure to bend the first wafer, thereby causing bonding contact of the first wafer and the second wafer.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area. As demand has grown recently for further miniaturization, higher speeds, greater bandwidth, and lower power consumption and latency, the need for smaller and more creative packaging techniques for semiconductor dies has grown.

As semiconductor technologies advance, stacked semiconductor devices, such as three-dimensional integrated circuits (3DIC), have emerged as an effective alternative, as they are able to reduce even further the physical size of the semiconductor device. Some methods of forming 3DICs involve bonding together two or more semiconductor wafers. Examples of commonly used bonding techniques include fusion bonding, eutectic bonding, direct metal-to-metal bonding, and hybrid bonding. Once two semiconductor wafers are bonded together, the interface between them may provide an electrically conductive path between the stacked semiconductor wafers.

Although existing wafer bonding apparatuses and methods have generally been adequate for their intended purposes, they have not been entirely satisfactory in all respects. Consequently, it would be desirable to provide a solution for improving the wafer bonding techniques.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1A is a schematic cross-sectional view of a wafer bonding apparatus in accordance with some embodiments.

FIG. 1B is a plan view of a wafer chuck of the wafer bonding apparatus in FIG. 1A in accordance with some embodiments.

FIGS. 2 to 4 are cross-sectional views illustrating a method of bonding wafers together using the wafer bonding apparatus in FIG. 1A at various intermediate stages of the wafer bonding process in accordance with some embodiments.

FIG. 5 is a schematic plan view illustrating the bonding wave direction using the wafer bonding process in FIGS. 2 to 4 in accordance with some embodiments.

FIG. 6A is a cross-sectional view illustrating a method of bonding wafers together using the wafer bonding apparatus in FIG. 1A at an intermediate stage of the wafer bonding process in accordance with some embodiments.

FIG. 6B is a schematic plan view illustrating the bonding wave direction using the wafer bonding process in FIG. 6A in accordance with some embodiments.

FIG. 7 is a cross-sectional view illustrating a method of bonding wafers together using the wafer bonding apparatus in FIG. 1A at an intermediate stage of the wafer bonding process in accordance with some embodiments.

FIGS. 8A and 8B are plan views of a wafer chuck in accordance with some embodiments, showing different arrangements of bonding pins.

FIG. 9 is a schematic cross-sectional view of a wafer bonding apparatus in accordance with some embodiments.

FIG. 10 is a schematic cross-sectional view of a wafer bonding apparatus in accordance with some embodiments.

FIG. 11A is a cross-sectional view illustrating a method of bonding wafers together using the wafer bonding apparatus in FIG. 10 at an intermediate stage of the wafer bonding process in accordance with some embodiments.

FIG. 11B is a schematic plan view illustrating the bonding wave direction using the wafer bonding process in FIG. 11A in accordance with some embodiments.

FIG. 12 is a flowchart illustrating a method for bonding wafers in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The system may be otherwise oriented (rotated 90 degrees or at other orientations) and the spatially relative descriptors used herein may likewise be interpreted accordingly.

Wafer bonding apparatuses and methods are provided. In accordance with some embodiments of the present disclosure, a wafer bonding apparatus for bonding two wafers together is provided. The wafer bonding apparatus includes two wafer chucks, and each wafer chuck is provided with a plurality of bonding pins which can extend through the chuck to apply pressure to bend (i.e., bow) the wafers, thereby causing bonding contact of the wafers. Each bonding pin can be independently and selectively controlled (i.e., activated) during the wafer bonding process. In some embodiments, the initial bonding contact (position) of the two wafers can also be determined and adjusted according to the different curvatures (e.g., warpage) of the incoming wafers. Thus, it facilitates better control the bonding wave propagation behavior. Consequently, the performance of the wafer bonding process is improved, especially in asymmetrical wafer bonding. The Embodiments discussed herein provide examples to enable making or using the subject matter of this disclosure, and a person having ordinary skill in the art will readily understand that modifications can be made while remaining within the contemplated scope of different embodiments. Throughout the various views and illustrative embodiments, like reference numbers are used to designate like elements. Although method embodiments may be discussed as being performed in a particular order, other method embodiments may be performed in any logical order.

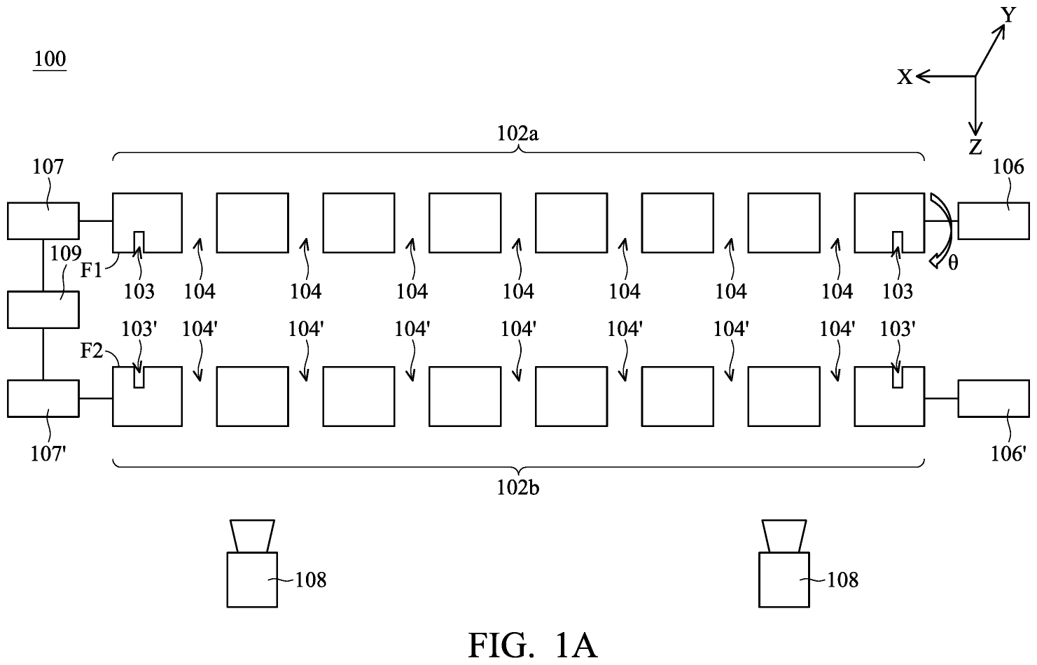

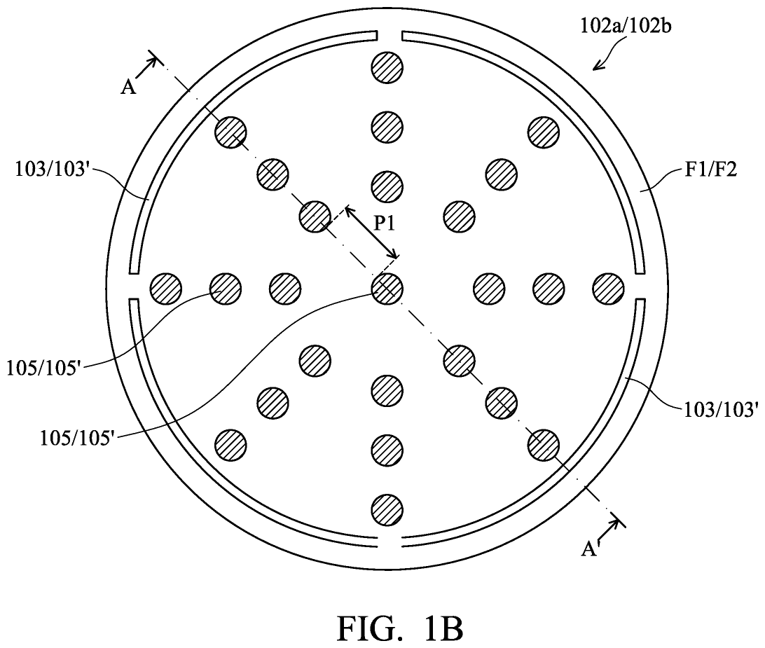

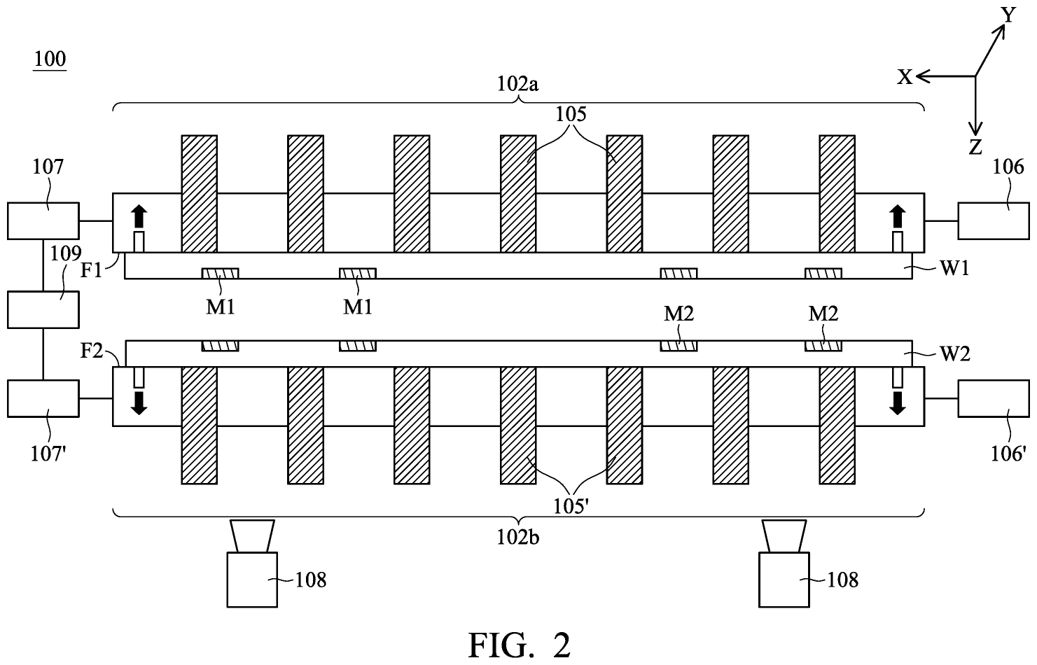

FIG. 1A is a schematic cross-sectional view of a wafer bonding apparatus 100 in accordance with some embodiments. The wafer bonding apparatus 100 includes a first wafer chuck 102a (hereinafter also referred to as a first chuck 102a) and a second wafer chuck 102b (hereinafter also referred to as a second chuck 102b) that can be positioned to face each other. For example, the first chuck 102a is configured to hold a first wafer (not shown in FIG. 1A; see first wafer W1 shown in FIG. 2) on its holding surface F1 (e.g., the lower surface shown), and the second chuck 102b is configured to hold a second wafer (not shown in FIG. 1A; see second wafer W2 shown in FIG. 2) on its holding surface F2 (e.g., the upper surface shown).

The first chuck 102a comprises any suitable material that may be processed to have vacuum grooves 103 formed on the holding surface F1, and the second chuck 102b comprises any suitable material that may be processed to have vacuum grooves 103′ formed on the holding surface F2. In some embodiments, silicon-based materials (such as glass, silicon oxide, and silicon nitride), other materials (such as aluminum oxide), and combinations of these materials can be used to form the first chuck 102a and the second chuck 102b. The first chuck 102a and the second chuck 102b may generally have the same shape and size (i.e., diameter).

FIG. 1B is a plan view of a wafer chuck 102a/102b of the wafer bonding apparatus 100 in FIG. 1A in accordance with some embodiments, where the cross-sectional views of the first chuck 102a and the second chuck 102b shown in FIG. 1A are taken along the section A-A′ shown in FIG. 1B. As shown in FIG. 1B, vacuum grooves 103/103′ are generally arranged along the edge regions of the chuck 102a/102b. In some alternatively embodiments, the vacuum grooves can be replaced by a single continuous vacuum groove. The first chuck 102a may have a diameter that is suitable to hold the first wafer W1, and the second chuck 102b may have a diameter that is suitable to hold the second wafer W2.

In some embodiments, the vacuum grooves 103 of the first chuck 102a are fluidly coupled to a first vacuum pump 106, as shown in FIG. 1A. During operation, the first vacuum pump 106 will evacuate the gas from the vacuum grooves 103, thereby lowering the pressure within the vacuum grooves 103. When the first wafer W1 is placed against the holding surface F1 of the first chuck 102a and the pressure within the vacuum grooves 103 have been reduced by the first vacuum pump 106, the pressure difference between the side of the first wafer W1 facing the vacuum grooves 103 and the side of the first wafer W2 facing away from the vacuum grooves 103 will hold the first wafer W1 against the holding surface F1 (for example, see FIG. 2). Similarly, the vacuum grooves 103′ of the second chuck 102b are fluidly coupled to a second vacuum pump 106′. The vacuum grooves 103′ and the second vacuum pump 106′ are similar to the vacuum grooves 103 and the first vacuum pump 106 discussed above, and their details are not repeated here.

In accordance with some embodiments, the first chuck 102a also includes apertures 104 formed therein, (e.g., extending from one side of the first chuck 102a to the other side), as shown in FIG. 1A. Each aperture 104 is configured to accommodate a first bonding pin (not shown in FIG. 1; see bonding pins 105 shown in FIG. 1B and FIG. 2). Similarly, the second chuck 102b also includes apertures 104′ formed therein, (e.g., extending from one side of the second chuck 102b to the other side), and each aperture 104′ is configured to accommodate a second bonding pin (not shown in FIG. 1; see bonding pins 105′ shown in FIG. 1B and FIG. 2). During the process of bonding the first wafer W1 and the second wafer W2, pressure is applied using the extended bonding pins 105 and 105′, as explained in greater detail below.

In some embodiments, as shown in FIG. 1B, for each wafer chuck 102a/102b, the bonding pins 105/105′ are arranged in such a way that one bonding pin 105/105′ is located substantially in the center region of the wafer chuck 102a/102b, and the other bonding pins 105/105′ are arranged to extend radially from the center region of the wafer chuck 102a/102b in different directions. Different arrangements (e.g., patterns) of the bonding pins 105/105′ may also be used in other embodiments, which will be described later. In some embodiments, all bonding pins 105/105′ are located in a region surrounded by the vacuum grooves 103/103′. In some embodiments, in the radial direction of the wafer chuck 102a/102b, there is a substantially constant pitch P1 between the bonding pins 105/105′, for example in a range between 2 cm and 3 cm.

Referring further to FIG. 1A, a first motor 107 is coupled to the first chuck 102a and a second motor 107′ is coupled to the second chuck 102b in accordance with some embodiments. In other embodiments, one motor 107 may be coupled to both of only one of the first chuck 102a and the second chuck 102b. In some embodiments, each motor 107/107′ may comprise a piezoelectric motor, a linear motor, or the like. Alternatively, each motor 107/107′ may comprise other types of motors. In some embodiments, the motors 107 and 107′ are configured to adjust an x position, a y position, a z position, and/or an angular position (θ) of the first chuck 102a relative to the second chuck 102b, and thus the first wafer W1 relative to the second wafer W2. In addition, in some embodiments, the motors 107 and 107′ are coupled to the bonding pins 105 and 105′, respectively, and they can control the extension and retraction of the bonding pins 105/105′ from the wafer chuck 102a/102b.

In some embodiments, one or more alignment monitors 108 are provided, and are connected to the motors 107 and 107′ using, for example, wiring (not specifically shown in FIG. 1A). In some embodiments, each alignment monitor 108 comprises an infrared (IR) charge coupled device (CCD) scope or the like, and can emit infrared (IR) or visible electromagnetic energy towards and through, for example, the second wafer chuck 102b in order to check the alignment of the second wafer W2 relative to the first wafer W1. This information may then be passed to the motors 107 and 107′ in order to perform any corrections that may be needed prior to initiating the process of bonding the first wafer W1 and the second wafer W2.

Additionally, in the illustrated embodiment, the wafer bonding apparatus 100 also includes a controller 109. The controller 109 may, for example, be a workstation computer that is capable of implementing a procedure for controlling the operation of the wafer bonding apparatus 100, including each module (e.g., the vacuum pumps 106 and 106′, the motors 107 and 107′, and the alignment monitors 108). In some embodiments, the controller 109 comprises one or more electronic processors that can control the automated process of the wafer bonding apparatus 100 that is described below. It may, for example, follow the procedure supplied by a memory module (e.g., a non-transitory medium) in the controller 109 or remote from the wafer bonding apparatus 100.

FIGS. 2 to 4 are cross-sectional views illustrating a method of bonding a first wafer W1 and a second wafer W2 together using the wafer bonding apparatus 100 in FIG. 1A at various intermediate stages of the wafer bonding process in accordance with some embodiments. The wafer bonding apparatus 100 are adapted to bond the first wafer W1 and the second wafer W2 together using fusion bonding, eutectic bonding, hybrid bonding, or other types of semiconductor wafer bonding known in the art.

FIG. 2 illustrates a placement of the first wafer W1 and the second wafer W2 onto the first chuck 102a and the second chuck 102b, respectively. The first wafer W1 may comprise a semiconductor substrate (not shown), which may be a bulk silicon, doped or undoped, or a layer of a silicon-on-insulator (SOI) substrate. Generally, an SOI substrate comprises a layer of a semiconductor material such as silicon, germanium, silicon germanium, SOI, silicon germanium on insulator (SGOI), or a combination thereof. Other substrates such as multi-layered substrates, gradient substrates, or hybrid orientation substrates may also be used.

Additionally, the first wafer W1 may also comprise various devices (e.g., transistors, resistors, capacitors, or the like), dielectric and metallization layers (not individually shown) over the semiconductor substrate in order to form a plurality of dies on the first wafer W1. These dies may be any suitable type of die, such as an application specific integrated circuit (ASIC) device, an imaging sensor, a logic die, or a memory device. However, any other suitable type of device, such as the system on a chip (SoC) type of device, may alternatively be utilized.

The second wafer W2 may be similar to the first wafer W1. It may, for example, comprise a semiconductor substrate such as bulk silicon, a layer of an SOI substrate, or the like. Alternatively, the second wafer W2 may be an insulating layer on a semiconductor layer that will be bonded to the first wafer W1 in order to form an SOI substrate. Any suitable combination of materials that need to be bonded together may alternatively be utilized, and all such combinations are fully intended to be included within the scope of the embodiments.

Additionally, the second wafer W2 may also comprise various devices (e.g., transistors, resistors, capacitors, or the like), dielectric and metallization layers (not individually shown) over the semiconductor substrate in order to form a plurality of dies on the second wafer W2. These dies may be any suitable type of die, such as an ASIC device, an imaging sensor, a logic die, a memory device, or the like. However, any other suitable type of device, such as the SoC type of device, may alternatively be utilized.

For example, the first wafer W1 may comprise a wafer with a plurality of ASIC dies, and the second wafer W2 may comprise a wafer with SOC devices on it that are desired to be bonded to the ASIC dies on the first wafer W2.

In some embodiments, the first wafer W1 further has first alignment marks M1 and the second wafer W2 has second alignment marks M2. The first alignment marks M1 and the second alignment marks M2 may be formed in the first wafer W1 and the second wafer W2 using, for example, a patterning process. The first alignment marks M1 and the second alignment marks M2 can be used to assist in the positioning of the first wafer W1 relative to the second wafer W2 during subsequent wafer bonding process steps.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In some embodiments, before placing the first wafer W1 on the first chuck 102a and placing the second wafer W2 on the second chuck 102b, a wafer metrology tool (not specifically shown) can be used to measure the warpage of the first wafer W1 and second wafer W2 to learn whether the incoming wafer is bowed symmetrically or asymmetrically, as well as to determine the degree of curvature at different locations on the wafer. Additionally or alternatively, in some embodiments, the wafer metrology tool may be used to measure the uniformity of the thickness of the material films (which were formed in previous processes) on the wafers. Any suitable metrology tool known in the art may be used as the wafer metrology tool. The measured information may then be passed to the controller 109 so that it can determine an appropriate procedure for the subsequent wafer bonding process.

Optionally, before placing the first wafer W1 on the first chuck 102a and placing the second wafer W2 on the second chuck 102b, in some embodiments, the first wafer W1 and/or the second wafer W2 may be exposed to a plasma process. The plasma process activates the wafer surface and facilitates the subsequent bonding process. In some embodiments, the first wafer W1 and/or the second wafer W2 are cleaned after the plasma process. The cleaning process may comprise the use of cleaning arms, a mega-sonic transducer, a rinse system, a drain system, and a spin module to keep the wafer surface clean and activated. A cleaning solvent including deionized (DI) water, acid, and/or base can be used to remove or protect the bonding surface, for example. Alternatively, other cleaning solvents and processes may be used. Neither the plasma process nor the cleaning process are included in some other embodiments.

Referring again to FIG. 2, in the illustrated embodiment, the first wafer W1 and the second wafer W2 are respectively placed onto the first chuck 102a and the second chuck 102b in a planar state. Once the wafer W1/W2 is in place on the wafer chuck 102a/102b, the vacuum pump 106/106′ is initiated, reducing the pressure within the vacuum grooves 103/103′ (see FIGS. 1A and 1B) relative to ambient pressure, and holing the wafer W1/W2 to the wafer chuck 102a/102b by vacuum. In some embodiments, the wafer W1/W2 may be intrinsically warped and the shape of the wafer W1/W2 may change when the vacuum pump 106/106′ is initiated and may conform to the shape (e.g., planar) of the holding surface F1/F2 (see FIG. 1). In the step of FIG. 2, the bonding pins 105/105′ are retracted in the wafer chuck 102a/102b.

As mentioned above, the alignment monitors 108 and the motors 107, 107′ are electrically connected together. In some embodiments, the alignment monitors 108 are activated to emit the IR or visible electromagnetic energy towards and through the second chuck 102b, the second wafer W2, and the second alignment marks M2 on the second wafer W2 to the first alignment marks M1 on the first wafer W1. The motors 107 and 107′ receive the information from the alignment monitors 108 regarding the relative position of the first wafer W1 and the second wafer W2, and adjust the position of the first wafer W1 relative to the position of the second wafer W2 to align the wafers W1 and W2.

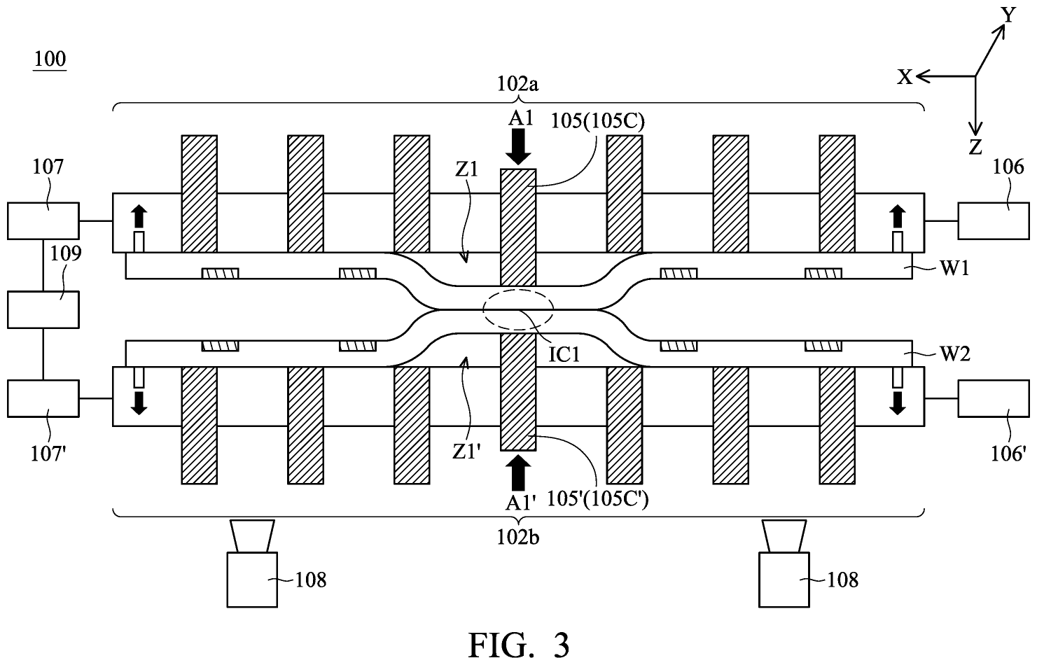

FIG. 3 illustrates an initiating of a wafer bonding process to bond the first wafer W1 and the second wafer W2. In the illustrated embodiment, the first chuck 102a and the second chuck 102b are moved (e.g., by the motors 107 and 107′) relative to each other such that the first alignment marks M1 and the second alignment marks M2 are aligned with each other. Once aligned, the bonding pin 105 (hereinafter referred to as a center bonding pin 105C) located in the center region of the first chuck 102a is extended (as indicated by the arrow A1) by the motor 107, contacts the side of the first wafer W1 that is attached to the holding surface F1 of the first chuck 102a and applies pressure to warp a portion the first wafer W1. At the same time, the bonding pin 105′ (hereinafter referred to as a center bonding pin 105C′) located in the center region of the second chuck 102b is also extended by the motor 107′ (as indicated by the arrow A1′), contacts the side of the second wafer W2 that is attached to the holding surface F2 of the second chuck 102b and applies pressure to warp a portion of the second wafer W2. Meanwhile, the first wafer W1 and the second wafer W2 remain secured by the vacuum created from the vacuum grooves 103 and 103′ of the wafer chucks 102a and 102b.

Referring further to FIG. 3, the warped first wafer W1 and the warped second wafer W2 are brought into contact at a first point IC1 (hereinafter referred to as an initial bonding contact point or position IC1). Once in contact, the first wafer W1 and the second wafer W2 will begin to bond at the first point IC1. In some embodiments, the first wafer W1 and the second wafer W2 are pressed together using a pressure of about 50 mN to about 1000 mN for a duration of about 30 seconds to about 120 seconds, as examples. Alternatively, other amounts of pressure and time durations may also be used. In the illustrated embodiment, the region around the warped portion of the first wafer W1 is hereinafter referred to as an activation zone Z1, and the region around the warped portion of the second wafer W2 is hereinafter referred to as an activation zone Z1′.

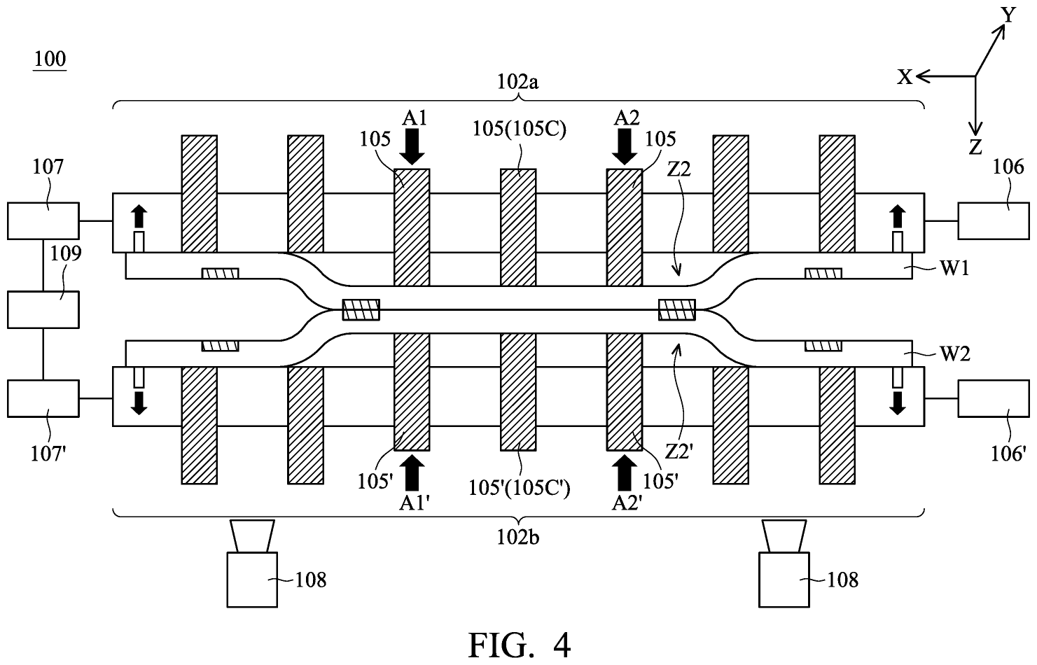

FIG. 4 illustrates a further bonding stage of the wafer bonding process. In the illustrated embodiment, with the center bonding pin 105C kept extended, the bonding pins 105 located near (e.g., around) the center region of the first chuck 102a are also extended (as indicated by the arrows A2) by the motor 107 and applies pressure to warp more portions the first wafer W1. At the same time, with the center bonding pin 105C′ kept extended, the bonding pins 105′ located near the center region of the second chuck 102b are also extended (as indicated by the arrows A2′) by the motor 107 and applies pressure to warp more portions the second wafer W2. Consequently, the activation zones Z1 and Z1′ expand into an activation zone Z2 and Z2′, respectively. Meanwhile, the first wafer W1 and the second wafer W2 remain secured by the vacuum created from the vacuum grooves 103 and 103′ of the wafer chucks 102a and 102b.

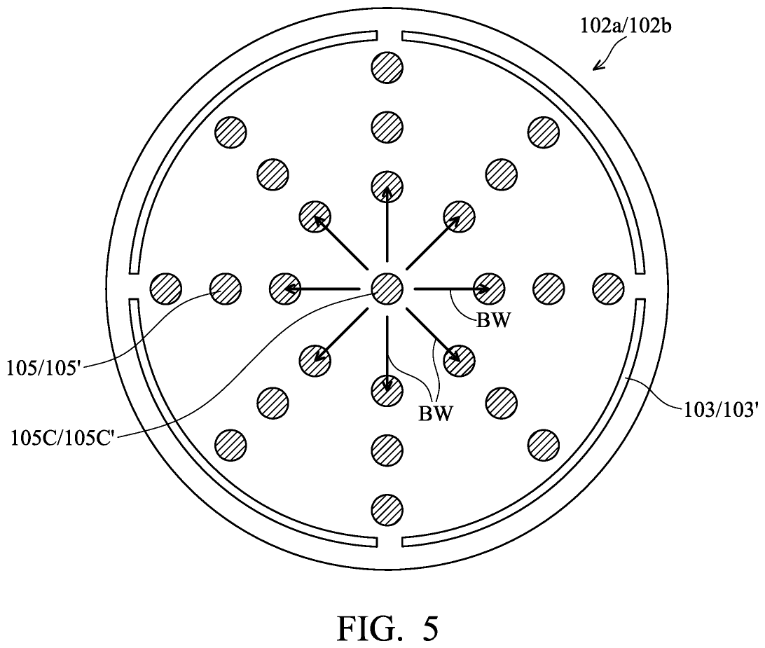

Thus, the bonding between the first wafer W1 and the second wafer W2 starts from the center region of the wafers W1 and W2 and spreads to edge regions of the wafers W1 and W2 in a radial and wave-like fashion (as indicated by the radial arrows BW shown in FIG. 5). Hence, the bonding method of the embodiments described above may be referred to as a wave-bonding method. In comparison with current bonding methods, the wave-bonding method reduces the number of bubbles that may be trapped between the two wafers W1 and W2 during bonding.

Although not shown, the wave-bonding method may continue to push and warp the wafers W1 and W2 with more peripheral bonding pins 105 and 105′ until the two wafers W1 and W2 are fully bonded together in accordance with some embodiments. By disposing multiple bonding pins 105/105′ (rather than just a center bonding pin 105C/105C′) in each wafer chuck 102a/102b, the bonding wave propagation behavior is better controlled.

It should be understood that the operation of the upper and lower bonding pins shown in FIGS. 2 to 5 is merely an illustrative example, and is not intended to be, and should not be construed to be, limiting to the present disclosure. For example, the number and position of actuated upper and lower bonding pins for each bonding stage can also vary in different embodiments, depending on the structure (e.g., the degree of curvature) of the wafers to be bonded.

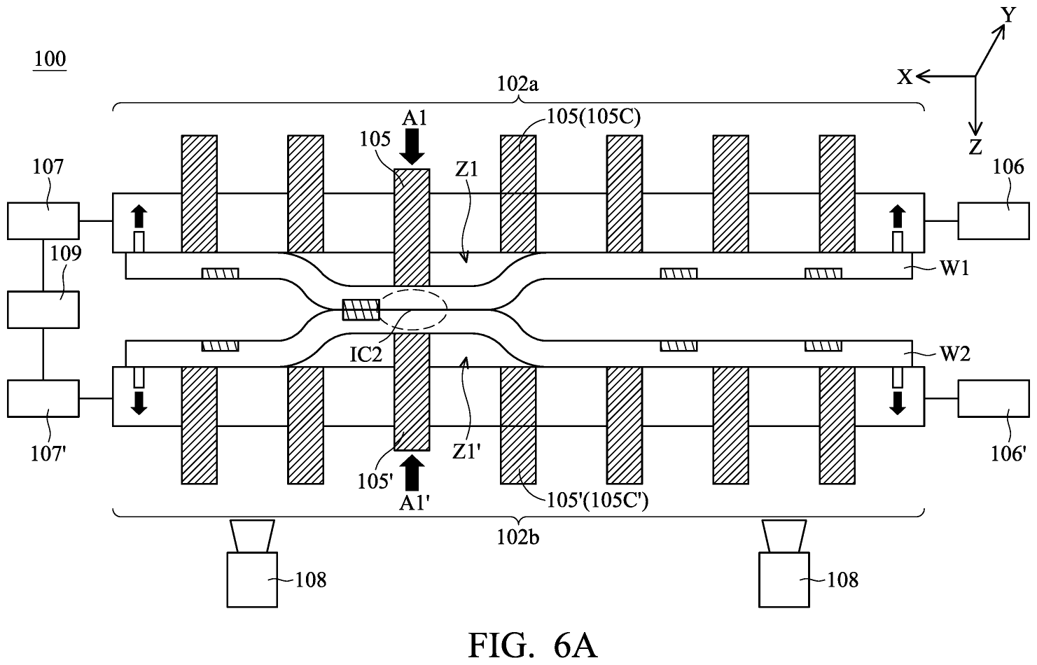

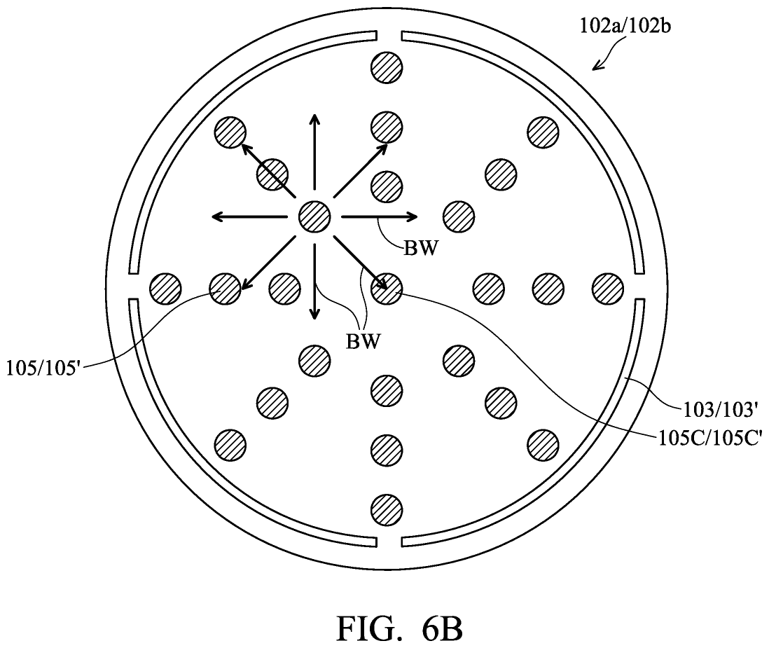

Also, it should be noted that the above-mentioned wafer bonding method in FIGS. 2 to 5 is suitable for cases where the two wafers W1 and W2 are symmetrical (for example, bowed symmetrically), but when one wafer is asymmetrical (for example, bowed asymmetrically), this wafer bonding method may not bond the two wafers W1 and W2 well. As mentioned above, before placing the first wafer W1 on the first chuck 102a and placing the second wafer W2 on the second chuck 102b, the warpage of the two incoming wafers W1 and W2 can be measured by a wafer metrology tool. Thus, if it is found that one of the wafers W1 and W2 is bowed asymmetrically, the wafer bonding method as shown in FIGS. 6A and 6B can be used instead.

Referring now to FIG. 6A, which illustrates an initiating of a wafer bonding process to bond the first wafer W1 and the second wafer W2, similar to that shown in FIG. 3 (the placement of the two wafers W1 and W2 can be the same as that shown in FIG. 2, and thus the details are not repeated here). In the illustrated embodiment, the first chuck 102a and the second chuck 102b are moved (e.g., by the motors 107 and 107′) relative to each other such that the first alignment marks M1 and the second alignment marks M2 are aligned with each other. Once aligned, a bonding pin 105 located near the center bonding pin 105C but not the center bonding pin 105C itself is extended (as indicated by the arrow A1) by the motor 107, contacts the side of the first wafer W1 that is attached to the holding surface F1 of the first chuck 102a and applies pressure to warp a portion the first wafer W1. At the same time, a bonding pin 105′ located near the center bonding pin 105C′ but not the center bonding pin 105C′ itself is also extended by the motor 107′ (as indicated by the arrow A1′), contacts the side of the second wafer W2 that is attached to the holding surface F2 of the second chuck 102b and applies pressure to warp a portion of the second wafer W2. Meanwhile, the first wafer W1 and the second wafer W2 remain secured by the vacuum created from the vacuum grooves 103 and 103′ of the wafer chucks 102a and 102b.

Referring further to FIG. 6A, the warped first wafer W1 and the warped second wafer W2 are brought into contact at a first point IC2 (hereinafter referred to as an initial bonding contact point or position IC2). Once in contact, the first wafer W1 and the second wafer W2 will begin to bond at the first point IC2. Unlike the embodiment shown in FIG. 3, the initial bonding contact point IC2 deviates from the center region of the wafers W1 and W2.

Although not shown, similar to the above-mentioned embodiments, the bonding method may continue to push and warp the wafers W1 and W2 with more peripheral bonding pins 105 and 105′ until the two wafers W1 and W2 are fully bonded together in accordance with some embodiments. The bonding wave propagation using the bonding method shown in FIG. 6A is indicated by the radial arrows BW shown in FIG. 6B.

This bonding wave control facilitates initial bonding contact position optimization for asymmetrical wafer bonding. For example, if one of the wafers W1 and W2 is asymmetrically bent and the point of the wafer with the greatest difference in height from the edge is in the second quadrant of the wafer (not specifically shown in FIG. 6B), then the bonding method with the initial bonding contact point IC2 set in the fourth quadrant (i.e., the opposite position; for example see FIG. 6B) of the wafer can correct (compensate for) this height difference and allow the two wafers W1 and W2 to bond together well at this point, whereas the bonding method where the initial bonding contact point IC1 is set at the center of the wafer cannot. It should be understood that the operation of the upper and lower bonding pins shown in FIGS. 6A and 6B is merely an illustrative example, and is not intended to be, and should not be construed to be, limiting to the present disclosure. Many alternatives and modifications will be apparent to those skilled in the art, once informed by the present disclosure.

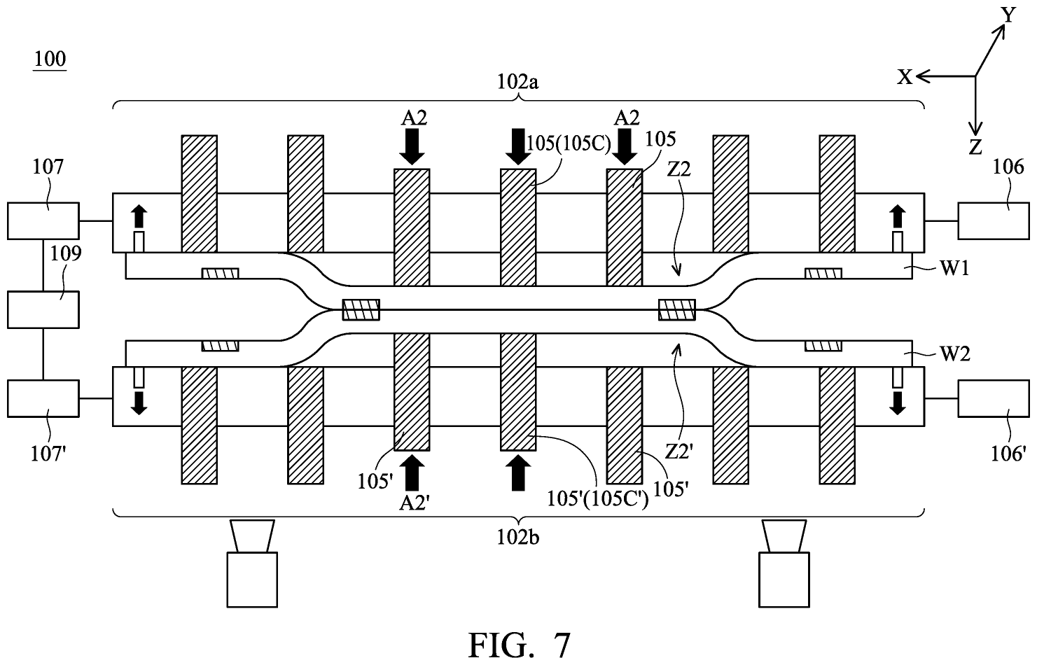

In addition, while in the above embodiments a pair of corresponding (i.e., vertically aligned) upper and lower bonding pins 105 and 105′ are activated (by the motors 106 and 106′) simultaneously to push the two wafers W1 and W2 simultaneously, the embodiment of the present disclosure is not limited thereto. In some other embodiments, a pair of corresponding upper and lower bonding pins 105 and 105′ can be activated separately (that is, while an upper bonding pin 105 is extended from the first chuck 102a, the corresponding lower pin 105′ is retracted in the second chuck 102b, and vice versa). For example, FIG. 7 illustrates that a pair of corresponding upper and lower bonding pins 105 and 105′ near the center bonding pin 105C/105C′ (e.g., on the right side of the center bonding pin 105C/105C′ as shown in FIG. 7) are activated separately (i.e., not activated simultaneously) at an intermediate stage of the wafer bonding process in accordance with some embodiments.

This bonding wave control helps to improve the overlay (OVL) performance of the resulting Wafer-on-Wafer (WoW) stacking structure, especially in cases where one of the wafers to be bonded has poor film-thickness uniformity that might otherwise adversely affect the overlay performance of the features of the bonded wafers (and thus the product performance). It should be understood that the operation of the upper and lower bonding pins shown in FIG. 7 is merely an illustrative example, and is not intended to be, and should not be construed to be, limiting to the present disclosure. Many alternatives and modifications will be apparent to those skilled in the art, once informed by the present disclosure.

Many variations and/or modifications can be made to embodiments of the disclosure. Some variations of some embodiments are described below.

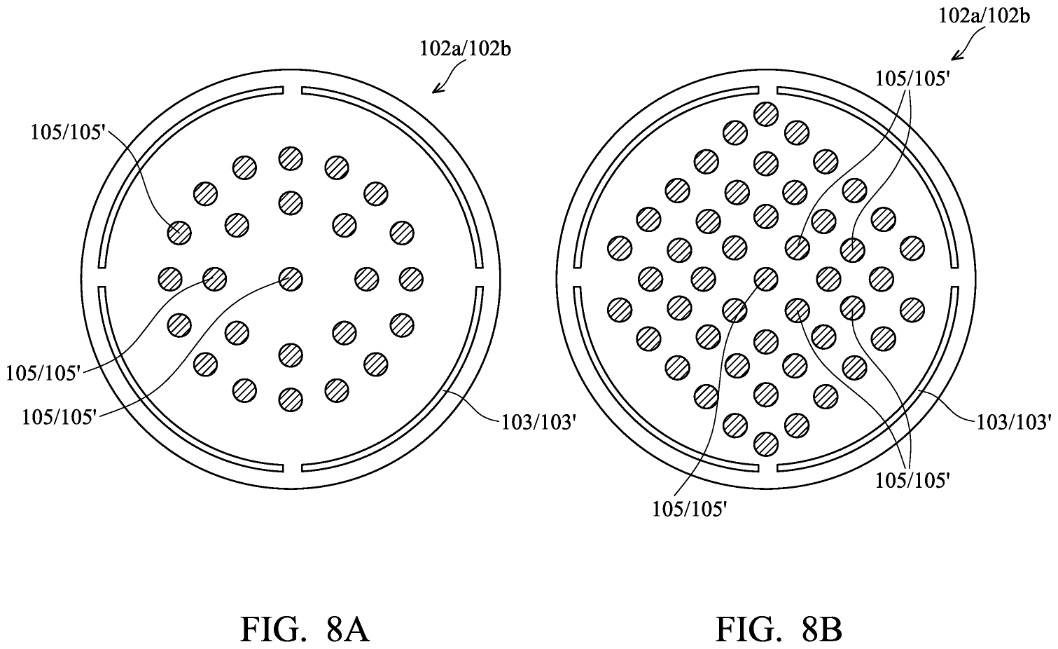

FIGS. 8A and 8B are plan views of a wafer chuck in accordance with some embodiments, showing different arrangements of bonding pins. In FIG. 8A, one of the bonding pins 105/105′ is located in the center region of the wafer chuck 102a/102b, and the other bonding pins 105/105′ are arranged in concentric circles. In FIG. 8B, one of the bonding pins 105/105′ is located in the center region of the wafer chuck 102a/102b, and the other bonding pins 105/105′ are arranged in a grid and evenly distributed in the entire wafer chuck 102a/102b. It should be understood that the geometries and configurations described herein are only illustrative, and are not intended to be, and should not be construed to be, limiting to the present disclosure. Many alternatives and modifications will be apparent to those skilled in the art, once informed by the present disclosure.

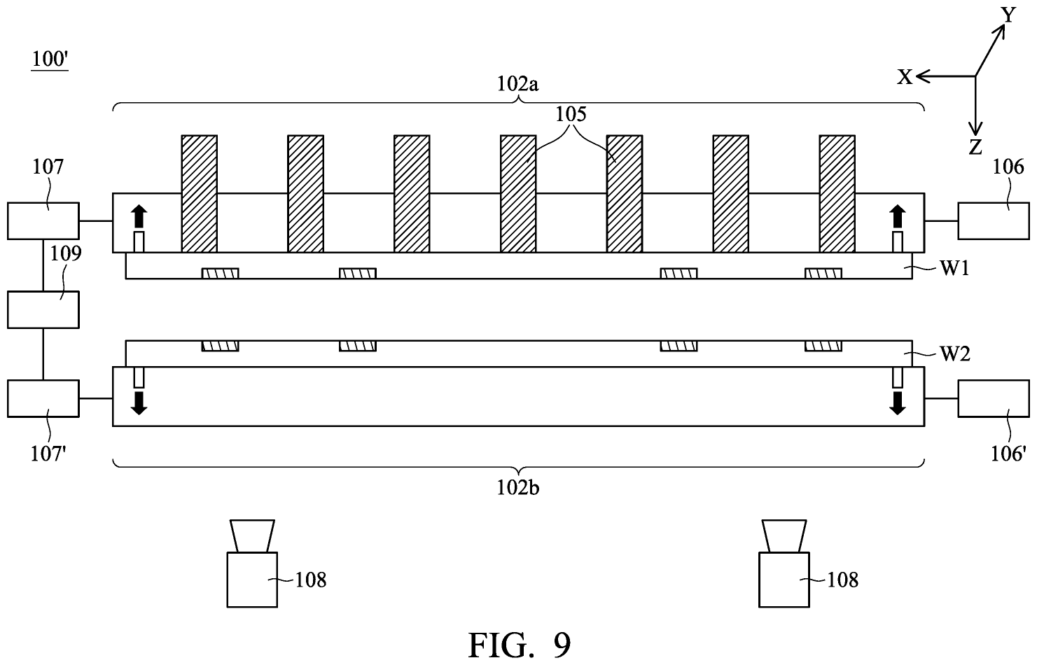

FIG. 9 is a schematic cross-sectional view of a wafer bonding apparatus 100′ in accordance with some embodiments. The wafer bonding apparatus 100′ differs from the wafer bonding apparatus 100 discussed above in that only the first chuck 102a has a plurality of bonding pins 105 therein, but the second chuck 102b does not. In some other embodiments, a plurality of bonding pins can only be disposed in the second chuck 102b of the wafer bonding apparatus 100′. Each bonding pin 105 of the wafer bonding apparatus 100′ can be independently controlled (by the controller 109) and actuated (by the motor 107) during the wafer bonding process to achieve the bonding wave control discussed with reference to FIGS. 2 to 6B.

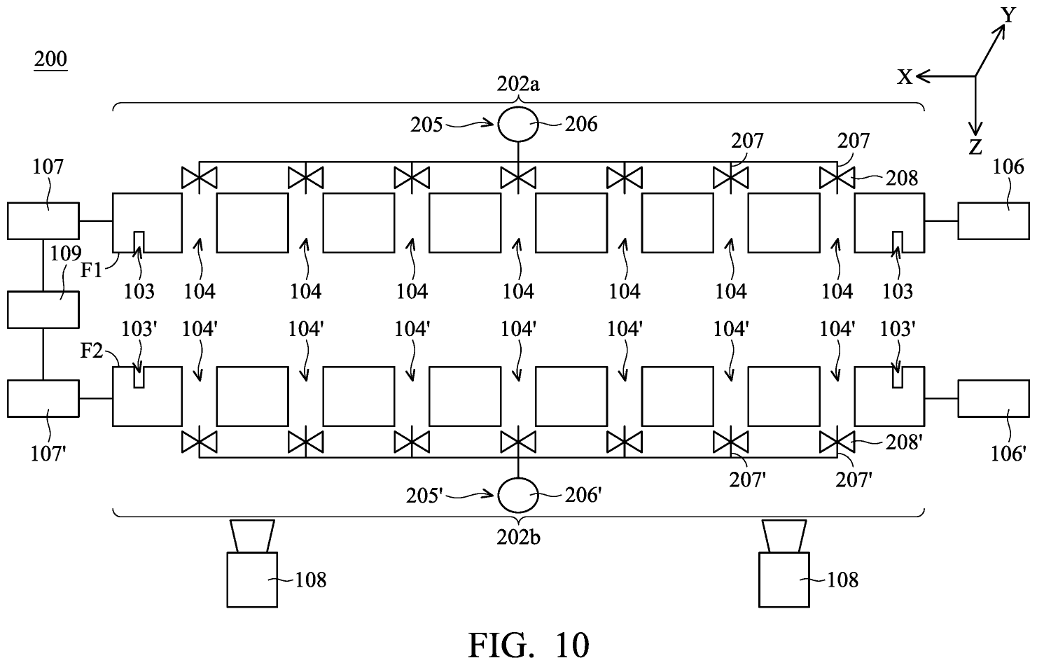

FIG. 10 is a schematic cross-sectional view of a wafer bonding apparatus 200 in accordance with some embodiments. The wafer bonding apparatus 200 includes a first wafer chuck 202a (hereinafter also referred to as a first chuck 202a) and a second wafer chuck 202b (hereinafter also referred to as a second chuck 202b), and their configuration and function are similar to those of the wafer chucks 102a and 102b of the wafer bonding apparatus 100 discussed above. The wafer chucks 202a and 202b differ from the wafer chucks 102a and 102b in that the bonding pins 105 and 105′ are replaced by a gas pressure generation module 205 and a gas pressure generation module 205′, respectively.

In the illustrated embodiment, the gas pressure generation module 205 includes a gas source 206 and a plurality of gas passageways 207. Each aperture 104 of the first chuck 202a is coupled to the gas source through one gas passageway 207. Each gas passageway 207 is provided with a pressure pump (not shown) and a valve 208. The pressure pump can be used to create a pressure so that gas (e.g., nitrogen gas or another suitable gas that does not harm the wafer) flows from the gas source 206, through the gas passageway 207 and into the corresponding aperture 104, thereby providing a gas pressure to the side of the first wafer W1 facing the holding surface F1 through the aperture 104. The valve 208 can be opened to allow gas to flow through, or closed so that the flow of gas stops. Similarly, the gas pressure generation module 205′ also includes a gas source 206′, a plurality of gas passageways 207′, and a plurality of pressure pumps (not shown) and valves 208′ disposed on the gas passageways 207′, and thus the details are not repeated. Although not shown, all valves 208 and 208′ of the gas pressure generation module 205 and 205′ are coupled to the controller 109, such that the controller 109 can independently and selectively control the opening and closing of each of the valves 208 and 208′ to control the gas pressure provided to different positions of the first wafer W1 and the second wafer W2. The amount of gas pressure and time durations can also be controlled (by the controller 109) to warpage and bond the wafers W1 and W2, similar to the function of the bonding pins 105 and 105′ in the above embodiments.

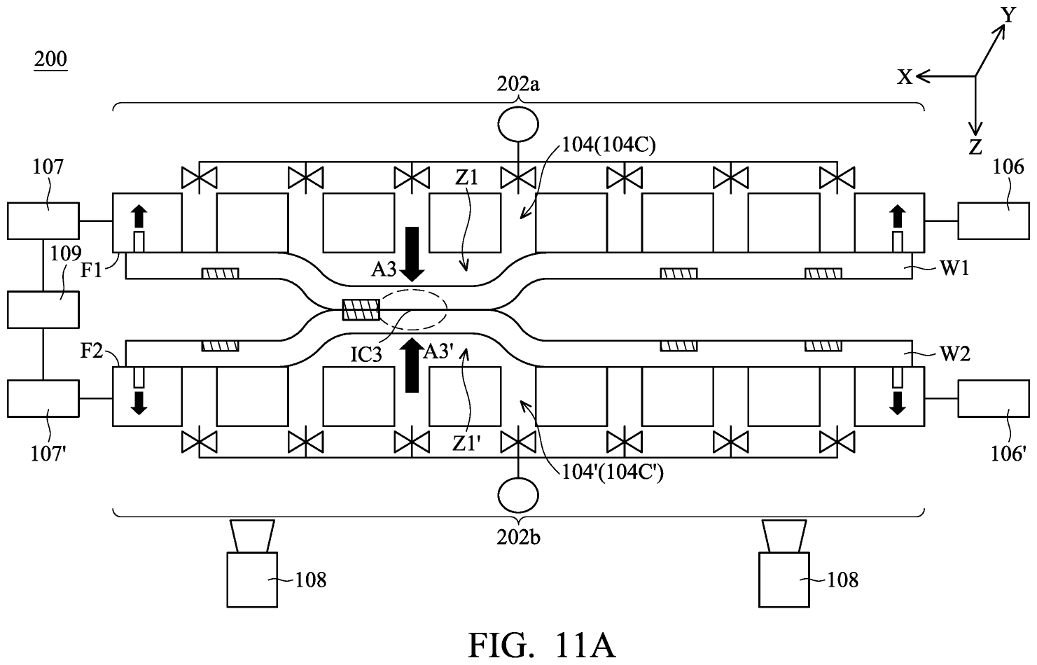

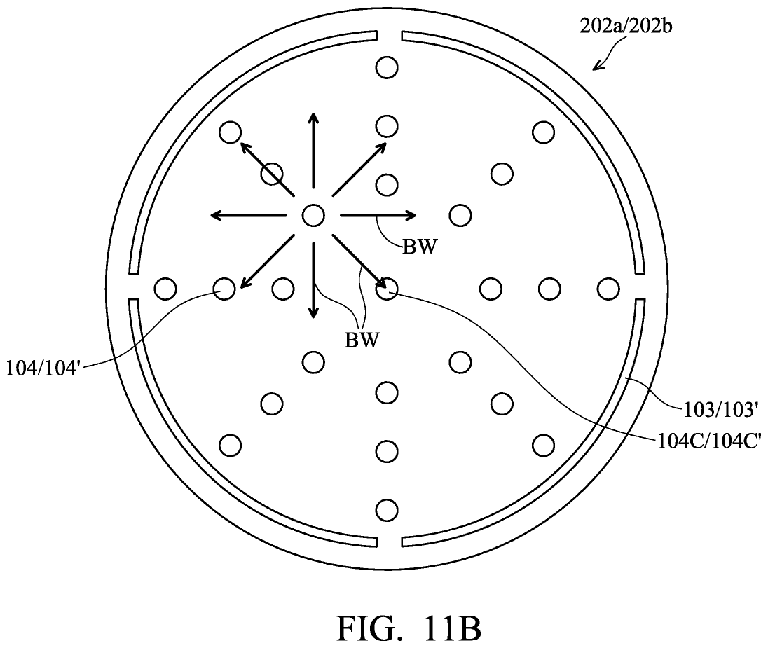

Thus, the wafer bonding apparatus 200 shown in FIG. 10 can also be used to perform the wafer bonding processes described with reference to FIGS. 2 to 7. For example, FIG. 11A illustrates an initiating of a wafer bonding process to bond the first wafer W1 and the second wafer W2 in accordance with some embodiments (the placement of the two wafers W1 and W2 can be the same as that shown in FIG. 2, and thus the details are not repeated here). In the illustrated embodiment, at least one of the incoming wafers W1 and W2 is bowed asymmetrically, as in the case illustrated in FIG. 6A. Thus, once the wafers W1 and W2 are coupled to the wafer chuck 202a and 202b and aligned with each other, the gas pressure generation modules 205 and 205′ are controlled (by the controller 109) so that gas pressure is supplied (as indicated by the arrow A3) to the first wafer W1 through an aperture 104 located near the center aperture 104C of the first chuck 202a (rather than through the center aperture 104C), and at the same time, gas pressure is also supplied (as indicated by the arrow A3′) to the second wafer W2 through an aperture 104′ located near the center aperture 104C′ of the second chuck 202b (rather than through the center aperture 104C′). Meanwhile, the first wafer W1 and the second wafer W2 remain secured by the vacuum created from the vacuum grooves 103 and 103′ of the wafer chucks 202a and 202b.

Referring further to FIG. 11A, the warped first wafer W1 and the warped second wafer W2 are brought into contact at a first point IC3 (hereinafter referred to as an initial bonding contact point or position IC3). Once in contact, the first wafer W1 and the second wafer W2 will begin to bond at the first point IC3. Similar to the embodiment shown in FIG. 6A, the initial bonding contact point IC3 deviates from the center region of the wafers W1 and W2. This bonding wave control facilitates initial bonding contact position optimization for asymmetrical wafer bonding.

Although not shown, similar to the above-mentioned embodiments, the bonding method may continue to push and warp the wafers W1 and W2 by providing gas pressure through more peripheral apertures 104 and 104′ until the two wafers W1 and W2 are fully bonded together in accordance with some embodiments.

Thus, the bonding between the first wafer W1 and the second wafer W2 starts from the relative center of the wafers W1 and W2 and spreads to the edge regions of the wafers W1 and W2 in a radial and wave-like fashion (as indicated by the radial arrows BW shown in FIG. 11B). Hence, the bonding method of the embodiments described above may also be referred to as a wave-bonding method. In comparison with current bonding methods, the wave-bonding method reduces the number of bubbles that may be trapped between the two wafers W1 and W2 during bonding.

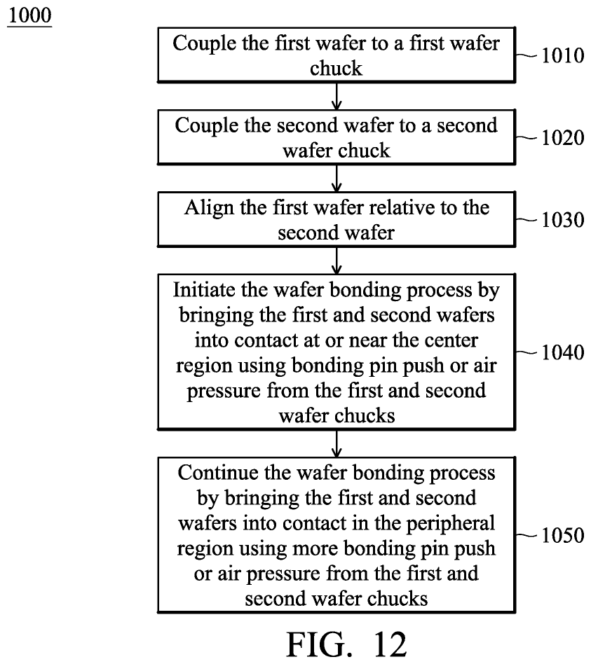

FIG. 12 is a flowchart illustrating a method 1000 for bonding wafers in accordance with some embodiments. In step 1010, the first wafer W1 is coupled to the first wafer chuck 102a/202a. In step 1020, the second wafer W2 is coupled to the second wafer chuck 102b/202b. In step 1030, the first wafer W1 is aligned to the second wafer W2 using the alignment monitors 108 and the motors 107, 107′. In step 1040, the wafer bonding process is initiated by bringing the first wafer W1 and the second wafer W2 into contact at the center region (e.g., the initial bonding contact point IC1) or near the center region (e.g., the initial bonding contact point IC2 or IC3) using bonding pin push (see FIG. 3 or 6A) or gas pressure (see FIG. 11A) from the first and second wafer chucks. In step 1050, the wafer bonding process continues by bringing the first wafer W1 and the second wafer W2 into contact in the peripheral region using more bonding pin push (see FIG. 4 or 7) or gas pressure from the first and second wafer chucks, until the two wafers W1 and W2 are fully bonded together.

In summary, the embodiments of the present disclosure have some advantageous features. By having multiple bonding pins (instead of just the center bonding pin) or multiple gas pressure holes (instead of just the center gas pressure hole) in one or both wafer chucks, and the bonding pins or gas pressure in different positions can be individually and selectively actuated or controlled, the bonding wave propagation behavior during the bonding process can be more precisely controlled. In addition, in some embodiments, the initial bonding contact position can also be determined and adjusted according to the different curvatures (e.g., warpage) of the incoming wafers. This facilitates initial bonding contact position optimization for asymmetrical wafer bonding. Accordingly, the performance (e.g., the OVL performance of the WoW stacking structure) of the wafer bonding process is improved by the bonding wave control.

In accordance with some embodiments, a wafer bonding apparatus is provided. The wafer bonding apparatus includes a first wafer chuck, a second wafer chuck, and a plurality of bonding pins. The first wafer chuck is configured to hold a first wafer. The second wafer chuck is configured to hold a second wafer. The bonding pins are accommodated in the first wafer chuck and configured to be movable through the first wafer chuck to apply pressure to bend the first wafer, thereby causing bonding contact of the first wafer and the second wafer.

In accordance with some embodiments, a wafer bonding method is provided. The wafer bonding method includes coupling a first wafer to a first wafer chuck. The wafer bonding method includes coupling a second wafer to a second wafer chuck. At least one of the first wafer chuck and the second wafer chuck is provided with a plurality of bonding pins configured to be movable to apply pressure to bend at least one of the first wafer and the second wafer. The wafer bonding method includes initiating the wafer bonding process by bringing the first wafer and the second wafer into contact at a first bonding position using at least one bonding pin. The wafer bonding method includes continuing the wafer bonding process by bringing the first wafer and the second wafer into contact in a second bonding position further from the center region of the first wafer and the second wafer than the first bonding position using at least another one bonding pin.

In accordance with some embodiments, a wafer bonding method is provided. The wafer bonding method includes coupling a first wafer to a first wafer chuck. The first wafer chuck is provided with a plurality of first apertures capable of applying gas pressure to bend the first wafer. The wafer bonding method includes coupling a second wafer to a second wafer chuck. The second wafer chuck is provided with a plurality of second apertures capable of applying gas pressure to bend the second wafer. The wafer bonding method includes initiating the wafer bonding process by bringing the first wafer and the second wafer into contact at a first bonding position using one first aperture and a corresponding second aperture. The first bonding position deviates from the center region of the first wafer and the second wafer. The wafer bonding method includes continuing the wafer bonding process by bringing the first wafer and the second wafer into contact in a second bonding position further from the center region of the first wafer and the second wafer than the first bonding position using more first apertures and more second apertures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A wafer bonding apparatus, comprising:
a first wafer chuck configured to hold a first wafer;
a second wafer chuck configured to hold a second wafer; and
a plurality of first bonding pins accommodated in the first wafer chuck and configured to be movable through the first wafer chuck to apply pressure to bend the first wafer, thereby causing bonding contact of the first wafer and the second wafer.

2. The wafer bonding apparatus as claimed in claim 1, wherein one of the plurality of first bonding pins is located in a center region of the first wafer chuck, and the other first bonding pins are located between the center region and edge regions of the first wafer chuck.

3. The wafer bonding apparatus as claimed in claim 2, wherein the other first bonding pins are arranged in radial directions of the first wafer chuck.

4. The wafer bonding apparatus as claimed in claim 2, wherein the other first bonding pins are arranged in concentric circles.

5. The wafer bonding apparatus as claimed in claim 2, wherein the other first bonding pins are arranged in a grid and evenly distributed in the entire first wafer chuck.

6. The wafer bonding apparatus as claimed in claim 1, further comprising:
a first motor coupled to the plurality of first bonding pins; and
a controller configured to control the first motor to independently move each of the plurality of first bonding pins.

7. The wafer bonding apparatus as claimed in claim 6, further comprising:
a plurality of second bonding pins accommodated in the second wafer chuck and configured to be movable through the second wafer chuck to apply pressure to bend the second wafer, thereby causing bonding contact of the first wafer and the second wafer; and
a second motor coupled to the plurality of second bonding pins, wherein the controller is configured to control the second motor to independently move each of the plurality of second bonding pins.

8. The wafer bonding apparatus as claimed in claim 7, wherein a pair of corresponding bonding pins of the plurality of first bonding pins and the plurality of second bonding pins are moved simultaneously under the control of the controller.

9. The wafer bonding apparatus as claimed in claim 7, wherein a pair of corresponding bonding pins of the plurality of first bonding pins and the plurality of second bonding pins are moved separately under the control of the controller.

10. The wafer bonding apparatus as claimed in claim 1, wherein a pair of corresponding bonding pins of the plurality of first bonding pins and the plurality of second bonding pins are aligned vertically.

11. A wafer bonding method, comprising:
coupling a first wafer to a first wafer chuck;
coupling a second wafer to a second wafer chuck, wherein at least one of the first wafer chuck and the second wafer chuck is provided with a plurality of bonding pins configured to be movable to apply pressure to bend at least one of the first wafer and the second wafer;
initiating a wafer bonding process by bringing the first wafer and the second wafer into contact at a first bonding position using at least one of the plurality of bonding pins; and
continuing the wafer bonding process by bringing the first wafer and the second wafer into contact in a second bonding position further from a center region of the first wafer and the second wafer than the first bonding position using at least another one of the plurality of bonding pins.

12. The wafer bonding method as claimed in claim 11, wherein the bonding between the first wafer and the second wafer starts from the first bonding position, passes through the second bonding position, and spreads to edge regions of the first wafer and the second wafer in a radial and wave-like fashion.

13. The wafer bonding method as claimed in claim 11, further comprising:
measuring warpage of the first wafer and the second wafer using a wafer metrology tool; and
determining the first bonding position based on measurement information from the wafer metrology tool.

14. The wafer bonding method as claimed in claim 11, wherein when both the first wafer and the second wafer have symmetrical structures, the wafer bonding process is initiated by bringing the first wafer and the second wafer into contact at the first bonding position using a center bonding pin of the plurality of bonding pins, and the first bonding position is at the center region of the first wafer and the second wafer.

15. The wafer bonding method as claimed in claim 11, wherein when at least one of the first wafer and the second wafer has an asymmetrical structure, the wafer bonding process is initiated by bringing the first wafer and the second wafer into contact at the first bonding position using a bonding pin located near a center bonding pin of the plurality of bonding pins, and the first bonding position deviates from the center region of the first wafer and the second wafer.

16. The wafer bonding method as claimed in claim 11, wherein both the first wafer chuck and the second wafer chuck are provided with a plurality of bonding pins, and a pair of corresponding bonding pins of the plurality of bonding pins of the first wafer chuck and the second wafer chuck are simultaneously moved under the control of a controller during the wafer bonding process.

17. The wafer bonding method as claimed in claim 11, wherein both the first wafer chuck and the second wafer chuck are provided with a plurality of bonding pins, and a pair of corresponding bonding pins of the plurality of bonding pins of the first wafer chuck and the second wafer chuck are separately moved under the control of a controller during the wafer bonding process.

18. The wafer bonding method as claimed in claim 11, wherein the first wafer is vacuum coupled to the first wafer chuck, and the second wafer is vacuum coupled to the second wafer chuck.

19. A wafer bonding method, comprising:
coupling a first wafer to a first wafer chuck, wherein the first wafer chuck is provided with a plurality of first apertures capable of applying gas pressure to bend the first wafer;
coupling a second wafer to a second wafer chuck, wherein the second wafer chuck is provided with a plurality of second apertures capable of applying gas pressure to bend the second wafer;
initiating a wafer bonding process by bringing the first wafer and the second wafer into contact at a first bonding position using one of the plurality of first apertures and a corresponding one of the plurality of second apertures, wherein the first bonding position deviates from a center region of the first wafer and the second wafer; and
continuing the wafer bonding process by bringing the first wafer and the second wafer into contact in a second bonding position further from the center region of the first wafer and the second wafer than the first bonding position using more of the first apertures and more of the second apertures.

20. The wafer bonding method as claimed in claim 19, further comprising:
measuring warpage of the first wafer and the second wafer using a wafer metrology tool; and
determining the first bonding position based on measurement information from the wafer metrology tool.
